(19) United States
(12) Patent Application Publication
(10) Pub. No.: US 2026/0182463 A1
(43) Pub. Date: Jun. 25, 2026

(54) SEMICONDUCTOR DEVICE AND METHOD OF MANUFACTURING THE SAME

(71) Applicant: Renesas Electronics Corporation, Tokyo (JP)

(72) Inventor: Tatsuo TAKEBAYASHI, Tokyo (JP)

(21) Appl. No.: 19/357,227

(22) Filed: Oct. 14, 2025

(30) Foreign Application Priority Data
Dec. 25, 2024 (JP) 2024-228760

(51) Int. Cl. H10W 90/00; H10W 72/20; H10W 90/20

(52) U.S. Cl. CPC H10W 90/00; H10W 72/248; H10W 72/265; H10W 72/267; H10W 90/288; H10W 90/291; H10W 90/297; H10W 90/722

(57) ABSTRACT

A semiconductor device is provided that can improve heat dissipation while suppressing cracking in one of the topmost semiconductor chips among a plurality of semiconductor chips. The semiconductor device includes a plurality of semiconductor chips and a mold resin. The semiconductor chips are stacked and include a first semiconductor chip and a second semiconductor chip. The first semiconductor chip is located at the topmost position among the semiconductor chips and the second semiconductor chip is located at the bottommost position among the semiconductor chips. Each of the semiconductor chips has a lower surface and an upper surface located opposite the lower surface. The upper surface of the first semiconductor chip has, in a plan view, a peripheral region and a central region located inside the peripheral region. The mold resin is formed to cover the peripheral region and has a through-hole that at least partially exposes the central region.

### CROSS-REFERENCE TO RELATED APPLICATIONS

The disclosure of Japanese Patent Application No. 2024-228760 filed on December 25, 2024, including the specification, drawings and abstract is incorporated herein by reference in its entirety.

### BACKGROUND

This disclosure relates to a semiconductor device and a method for manufacturing the semiconductor device.

There are disclosed techniques listed below.

[Patent Document 1] Japanese Unexamined Patent Application Publication No. 9-64236

Patent Document 1 discloses a semiconductor device. Patent Document 1 discloses a semiconductor device having a wiring substrate, an integrated circuit chip, an underfill, and an encapsulant. The wiring substrate has a first surface, and a second surface located on the opposite side of the first surface. A plurality of terminal pads are formed on the second surface, and external terminals are formed on the terminal pads. The integrated circuit chip has a third surface and a fourth surface. The fourth surface is located on the opposite side of the third surface. The integrated circuit chip is arranged on the first surface such that the third surface faces the first surface. The fourth surface, in a plan view, has a peripheral region and a central region located inside the peripheral region. The underfill is filled between the wiring substrate and the integrated circuit chip. The encapsulant seals the wiring substrate and the integrated circuit chip. However, the encapsulant does not cover the central region of the fourth surface, and external terminals are exposed from the encapsulant.

### SUMMARY

In the semiconductor device described in Patent Document 1, when a plurality of integrated circuit chips are stacked, there is a risk of cracking occurring in the one located at the topmost position among the plurality of integrated circuit chips. Other problems and novel features will become apparent from the description herein and from the accompanying drawings.

The semiconductor device of this disclosure includes a plurality of semiconductor chips and a mold resin. The semiconductor chips are stacked. The semiconductor chips include a first semiconductor chip and a second semiconductor chip. The first semiconductor chip is located at the topmost position among the plurality of semiconductor chips and the second semiconductor chip is located at the bottommost position among the plurality of semiconductor chips. Each of the plurality of semiconductor chips has a lower surface and an upper surface located opposite the lower surface. The upper surface of the first semiconductor chip has, in a plan view, a peripheral region and a central region located inside the peripheral region. The mold resin is formed to cover at least the peripheral region and has a through-hole that at least partially exposes the central region.

According to the semiconductor device of this disclosure, it is possible to suppress the occurrence of cracking in the one located at the topmost position among the plurality of semiconductor chips while improving heat dissipation.

### BRIEF DESCRIPTION OF THE DRAWINGS

FIG. 1 is a plan view of the semiconductor device DEV1.

FIG. 2 is a cross-sectional view of the semiconductor device DEV1 at II-II in FIG. 1.

FIG. 3 is a plan view of the semiconductor chip CHP.

FIG. 4A is a cross-sectional view of the semiconductor chip CHP at IVA-IVA in FIG. 3.

FIG. 4B is a partially enlarged view of FIG. 4A.

FIG. 4C is a cross-sectional view of the semiconductor chip CHP in the vicinity of the through-hole-via TSV.

FIG. 5 is a manufacturing process diagram of the semiconductor device DEV1.

FIG. 6 is a cross-sectional view explaining the chip stacking process S2.

FIG. 7 is a cross-sectional view explaining the underfill filling process S3.

FIG. 8 is a cross-sectional view explaining the resin molding process S4.

FIG. 9 is a cross-sectional view of the semiconductor device DEV1A.

FIG. 10 is a cross-sectional view of the semiconductor device DEV1B.

FIG. 11 is a cross-sectional view explaining an example of the method for forming the through-hole TH2.

FIG. 12 is a plan view of the semiconductor device DEV1 according to a modified example.

FIG. 13 is a cross-sectional view of the semiconductor device DEV1 at XIII-XIII in FIG. 12 according to a modified example.

FIG. 14 is a cross-sectional view of the semiconductor device DEV2.

FIG. 15 is a cross-sectional view of the semiconductor device DEV3.

FIG. 16 is a cross-sectional view of the semiconductor device DEV4.

FIG. 17 is a cross-sectional view of the semiconductor device DEV5.

FIG. 18 is a bottom view of the semiconductor chip CHP in the semiconductor device DEV5.

FIG. 19 is a plan view of the semiconductor device DEV6.

FIG. 20 is a cross-sectional view of the semiconductor device DEV6 at XX-XX in FIG. 19.

### DETAILED DESCRIPTION

The details of the embodiments of this disclosure will be described with reference to the drawings. In the following drawings, the same reference numerals are used for the same or equivalent parts, and redundant explanations will not be repeated.

### First Embodiment

The semiconductor device DEV1 according to the first embodiment will be described below.

### Configuration of Semiconductor Device DEV1

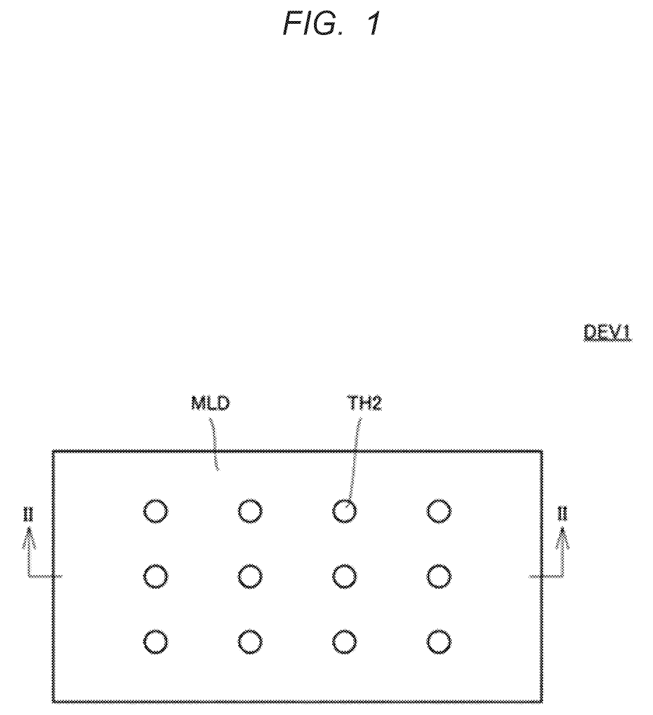

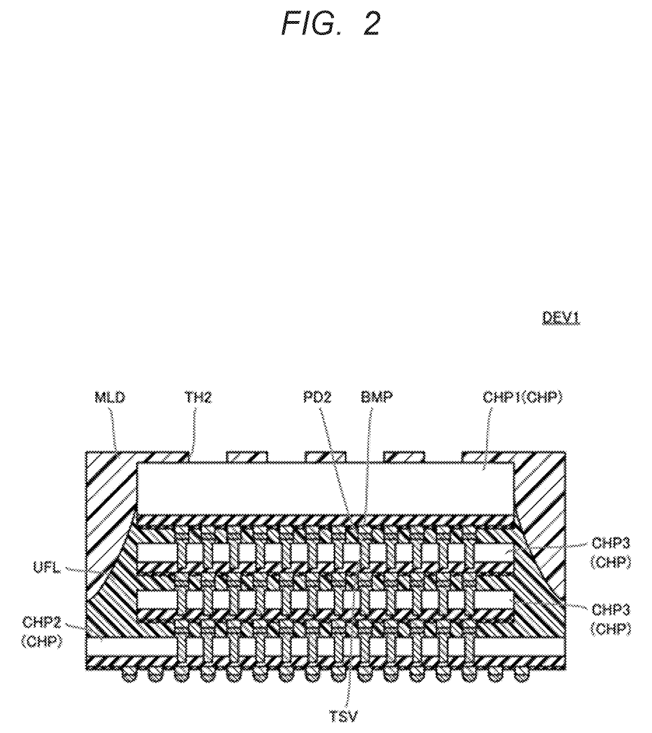

As shown in FIGS. 1 and 2, the semiconductor device DEV1 includes a plurality of semiconductor chips CHPs, an underfill UFL, and a mold resin MLD.

The plurality of semiconductor chips CHPs are stacked along the thick direction of the semiconductor device DEV1. The semiconductor chip CHP positioned at the topmost layer among the plurality of semiconductor chips CHPs is referred to as the semiconductor chip CHP1. The semiconductor chip CHP positioned at the bottommost layer among the plurality of semiconductor chips CHPs is referred to as the semiconductor chip CHP2. The semiconductor chips CHPs positioned between the semiconductor chip CHP1 and the semiconductor chip CHP2 among the plurality of semiconductor chips CHP are referred to as the semiconductor chips CHP3s. In the example shown in FIGS. 1 and 2, the number of semiconductor chip CHP3 is two, but the number of semiconductor chip CHP3 may be one or three or more. In plain view, the area of the semiconductor chip CHP2 is larger than the area of the semiconductor chip CHP1 and the area of the semiconductor chip CHP3. The thickness of the semiconductor chip CHP1 is greater than the thickness of the semiconductor chip CHP2 and the thickness of the semiconductor chip CHP3.

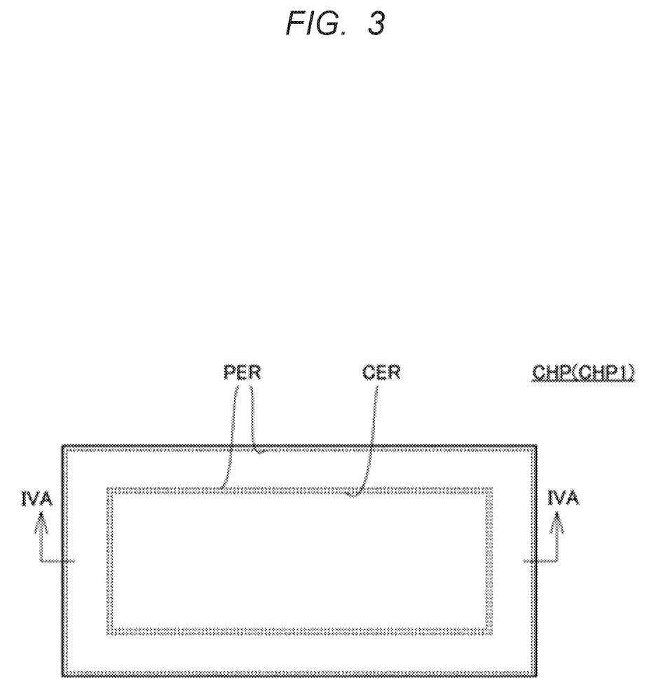

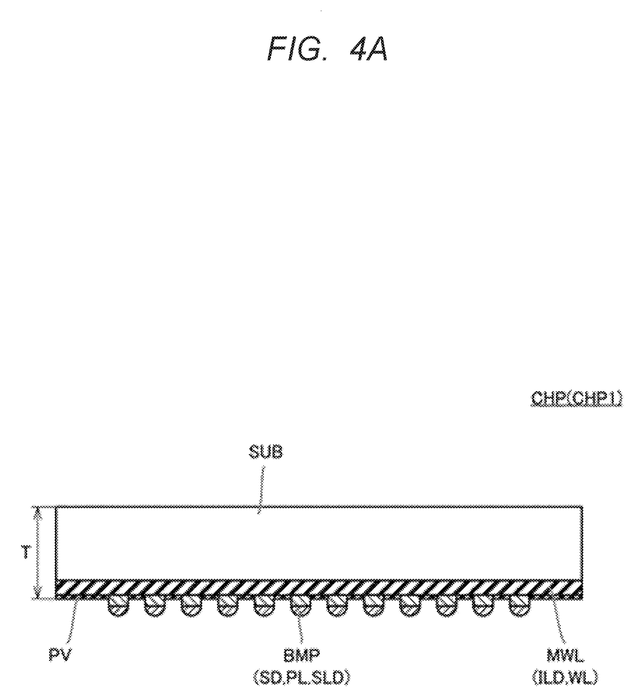

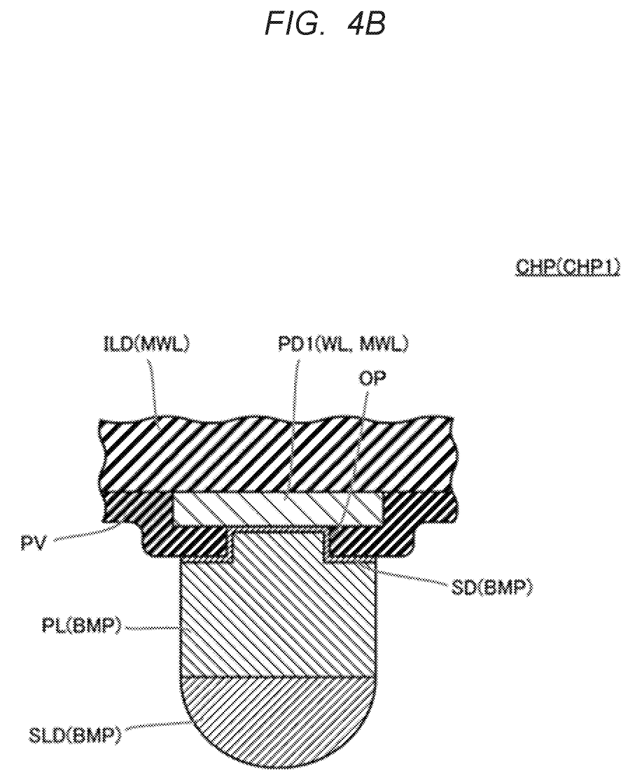

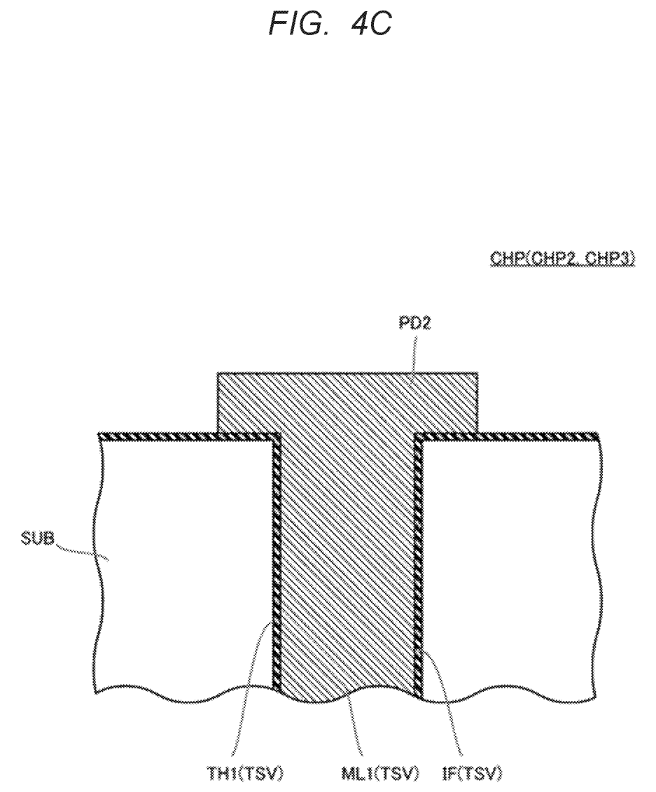

As shown in FIGS. 3, 4A, and 4B, the semiconductor chip CHP includes a semiconductor substrate SUB and a multilayer wiring layer MWL. Although not shown, within the semiconductor substrate SUB, source regions and drain regions of transistors are formed on the lower surface of the semiconductor substrate SUB. Also, although not shown, a gate insulating film of the transistor is formed on the channel region of the transistor located between the source region and the drain region. A gate electrode of the transistor is formed on the gate insulating film. The semiconductor substrate SUB is formed of, for example, single-crystal silicon.

The multilayer wiring layer MWL includes a plurality of interlayer insulating films ILDs, a plurality of wiring layers WLs, and a passivation film PV. The plurality of interlayer insulating films ILD are laminated on the lower surface of the semiconductor substrate SUB. The wiring layer WL is formed on one interlayer insulating film ILD and is covered by another interlayer insulating film ILD. However, the uppermost wiring layer WL (the wiring layer WL farthest from the semiconductor substrate SUB) is not covered by an interlayer insulating film ILD. The interlayer insulating films ILDs are formed of, for example, silicon oxide, and the wiring layers WLs are formed of a metal material such as aluminum or copper.

The uppermost wiring layer WL has a pad PD1. The passivation film PV is formed on the uppermost interlayer insulating film ILD to cover the uppermost wiring layer WL. An opening OP is formed in the passivation film PV to partially expose the pad PD1.

The semiconductor chip CHP further includes a bump BMP, which has a seed layer SD, a pillar PL, and a solder layer SLD. The seed layer SD is formed on the pad PD1 within the opening OP. The seed layer SD is also formed on the passivation film PV around the opening OP. The seed layer SD is, for example, a laminated film of a titanium layer and a copper layer formed on the titanium layer. The pillar PL is formed on the seed layer SD. The pillar PL is formed of, for example, copper or a copper alloy. The solder layer SLD is formed on the pillar PL. The solder layer SLD is formed of, for example, a tin alloy. However, the structure of the bump BMP is not limited to the structure shown in FIG. 4B. For example, a metal layer formed of nickel, or the like may be interposed between the pillar PL and the solder layer SLD.

As shown in FIG. 4C, a through-hole-via TSV is formed in the semiconductor chip CHP. However, the through-hole-via TSV is not formed in the semiconductor chip CHP1. The through-hole-via TSV includes a through-hole TH1, a metal layer ML1, and an insulating film IF.

The through-hole TH1 extends from the upper surface of the semiconductor substrate SUB to reach the multilayer wiring layer MWL. The insulating film IF is formed on the inner wall surface of the through-hole TH1. The insulating film IF is also formed on the lower surface of the semiconductor substrate SUB. Although not shown, the wiring layer WL is exposed from the through-hole TH1. The metal layer ML1 is formed within the through-hole TH1. The metal layer ML1 is formed of, for example, copper or a copper alloy. The insulating film IF is formed between the inner wall surface of the through-hole TH1 and the metal layer ML1. The insulation film IF is formed of, for example, silicon oxide.

The semiconductor chip CHP further includes a pad PD2. The pad PD2 is formed on the upper surface of the semiconductor substrate SUB with the insulating film IF interposed. The pad PD2 is formed of, for example, copper or a copper alloy. The pad PD2 is electrically connected to the through-hole-via TSV (metal layer ML1). By connecting the bump BMP of the upper semiconductor chip CHP to the pad PD2 of the lower semiconductor chip CHP, the two semiconductor chips CHP are stacked.

The underfill UFL is filled between two adjacent semiconductor chips CHPs among the plurality of semiconductor chips CHPs. The underfill UFL is also formed on the upper surface of the semiconductor chip CHP2 so as to cover the side surfaces of the semiconductor chip CHP1, the side surfaces of the semiconductor chip CHP2, and the side surfaces of the semiconductor chip CHP3.

The mold resin MLD covers the underfill UFL and the plurality of semiconductor chips CHPs. However, the underfill UFL may be exposed on the side surface of the semiconductor device DEV1. The upper surface of the semiconductor chip CHP1 has an outer peripheral region PER and a central region CER located inside the outer peripheral region PER in plain view. The mold resin MLD covers the upper surface of the semiconductor chip CHP1. The mold resin MLD only needs to cover at least the outer peripheral region PER. If the thickness of the semiconductor chip CHP1 is T, the width of the outer peripheral region PER is, for example, 1.6×T+0.35mm or more.

In the portion of the mold resin MLD covering the upper surface of the semiconductor chip CHP1, a plurality of through-holes TH2 are formed. The through-holes TH2 penetrate the mold resin MLD and expose the central region CER. The plurality of through-holes TH2 are arranged in a grid pattern in plain view, for example.

The mold resin MLD contains a filler. The filler is formed of, for example, silicon. On the other hand, the underfill UFL does not contain a filler. Therefore, the thermal expansion coefficient of the mold resin MLD is smaller than that of the underfill UFL.

### Manufacturing Method of Semiconductor Device DEV1

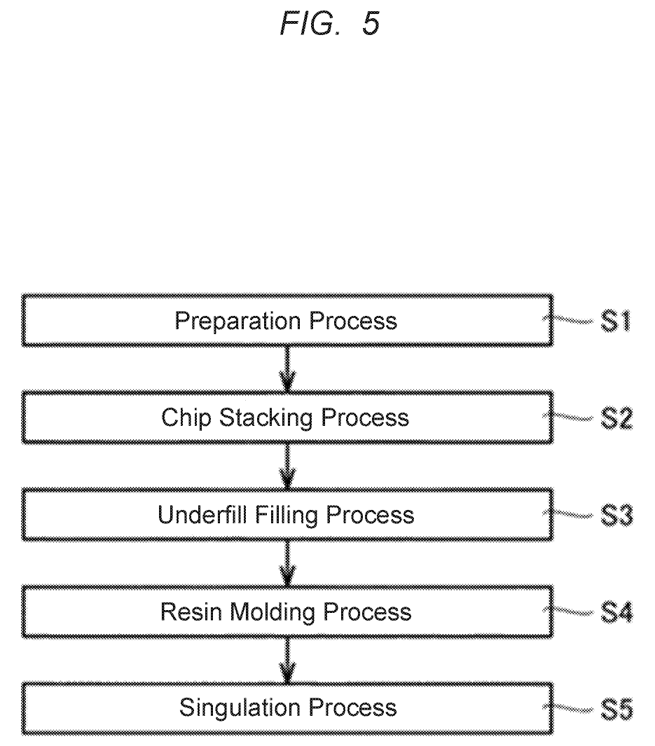

As shown in FIG. 5, the manufacturing method of the semiconductor device DEV1 includes a preparation process S1, a chip stacking process S2, an underfill filling process S3, a resin molding process S4, and a singulation process S5.

In preparation process S1, the semiconductor chips CHPs are prepared. In the preparation process S1, first, a semiconductor wafer is prepared. The semiconductor wafer includes a plurality of semiconductor chips CHPs. The structure of the semiconductor chip CHP included in the semiconductor wafer is the same as that of the semiconductor chip CHP in the semiconductor device DEV1, except that it is not singulated, the through-hole-via TSV is not formed, the pad PD2 is not formed, and the semiconductor substrate SUB is thick. Second, a glass carrier is attached to the lower surface of the semiconductor wafer. This protects the bump BMP and reinforces the semiconductor wafer.

Third, the semiconductor substrate SUB is polished on the upper surface side. This reduces the thickness of the semiconductor substrate SUB. Fourth, the through-hole-via TSV is formed. When forming the through-hole-via TSV, first, a through-hole TH1 is formed in the semiconductor substrate SUB and the multilayer wiring layer MWL by etching. Next, for example, by a CVD (Chemical Vapor Deposition) method, an insulating film IF is formed on the inner wall surface of the through-hole TH1, on the bottom surface of the through-hole TH1, and on the upper surface of the semiconductor chip CHP. Then, by anisotropic etching, the insulation film IF located at the bottom of the through-hole TH1 is removed. As a result, the wiring layer WL is exposed from the through-hole TH1. Next, for example, by sputtering, a seed layer is formed on the insulating film IF and on the wiring layer WL exposed from the through-hole TH1. Subsequently, by performing electrolytic plating using the seed layer, an electrolytic plating layer grows on the seed layer. Then, the electrolytic plating layer and the seed layer protruding from the through-hole TH1 are removed by, for example, a CMP (Chemical Mechanical Polishing) method, resulting in the remaining part becoming the metal layer ML1.

Fifth, a pad PD2 is formed on the insulating film IF. When forming the pad PD2, first, a seed layer is formed on the insulating film IF. Next, a resist pattern is formed on the seed layer. Then, the pad PD2 is grown by electrolytic plating on the seed layer exposed from the resist pattern. Subsequently, the seed layer beneath the resist pattern is removed by etching. Sixth, by dicing the semiconductor wafer along the boundary of the semiconductor chip CHP, the semiconductor wafer is divided into a plurality of semiconductor chips CHPs. It should be noted that when preparing the semiconductor chip CHP1, the process of forming the through-hole-via TSV and the pad PD2 is not performed. When preparing the semiconductor chip CHP2, the semiconductor wafer is not diced.

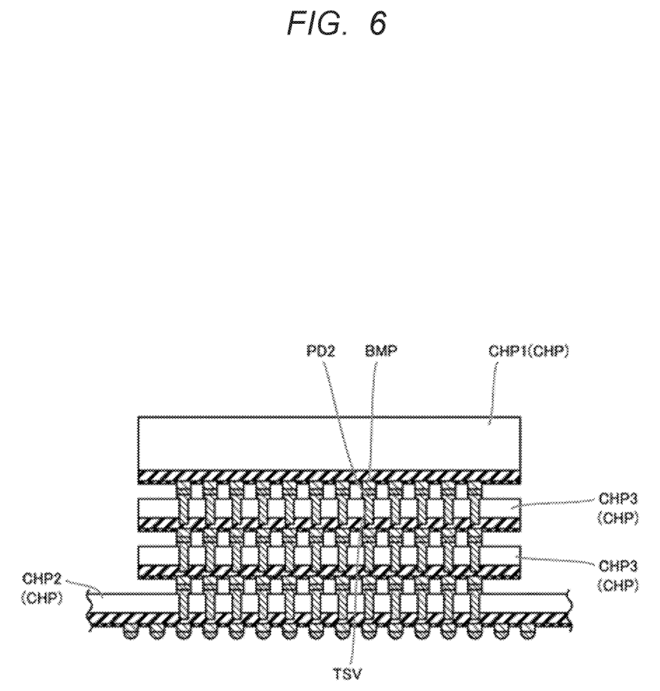

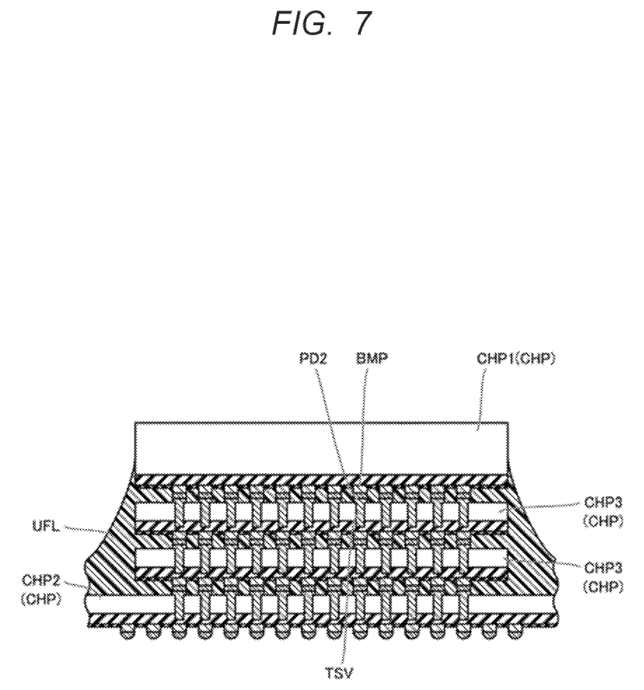

As shown in FIG. 6, in the chip stacking process S2, semiconductor chips CHP1 and CHP3 are stacked on semiconductor chip CHP2, and the bump BMP of the upper semiconductor chip CHP is connected to the pad PD2 of the lower semiconductor chip CHP. As shown in FIG. 7, in the underfill filling process S3, underfill UFL is filled between two adjacent semiconductor chips CHP among the plurality of semiconductor chips CHPs. In the underfill filling process S3, firstly, uncured underfill UFL is poured between two adjacent semiconductor chips CHP among the plurality of semiconductor chips CHPs. Secondly, by heating, the uncured underfill UFL is cured.

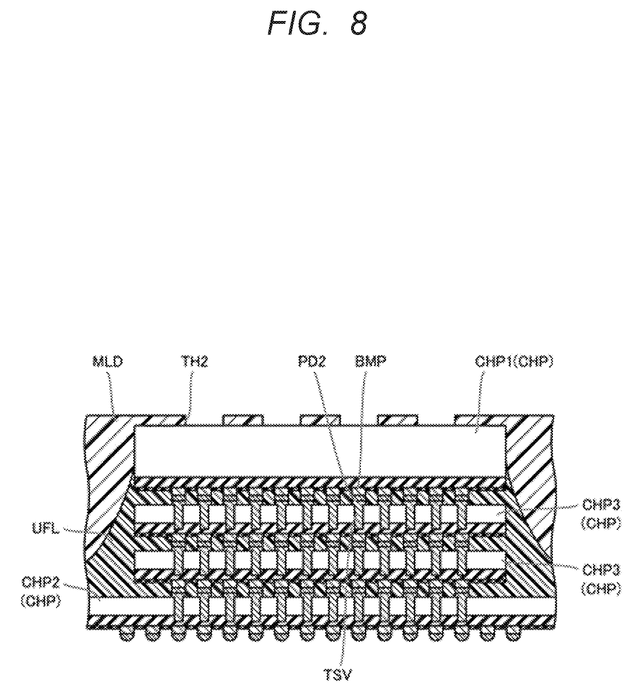

As shown in FIG. 8, in the resin molding process S4, for example, by the transfer molding method, the plurality of semiconductor chips CHPs and underfill UFL are covered with mold resin MLD. Protrusions are formed on the inner surface of the mold used at this time. By the protrusions contacting the upper surface of semiconductor chip CHP1, a through hole TH2 is formed in the part of the mold resin MLD located on the upper surface of semiconductor chip CHP1. In the singulation process S5, the semiconductor wafer including semiconductor chip CHP3, underfill UFL, and mold resin MLD are diced along the boundary of semiconductor chip CHP2. As a result, the semiconductor device DEV1 with the structure shown in FIGS. 1 and 2 is obtained.

### Effects of Semiconductor Device DEV1

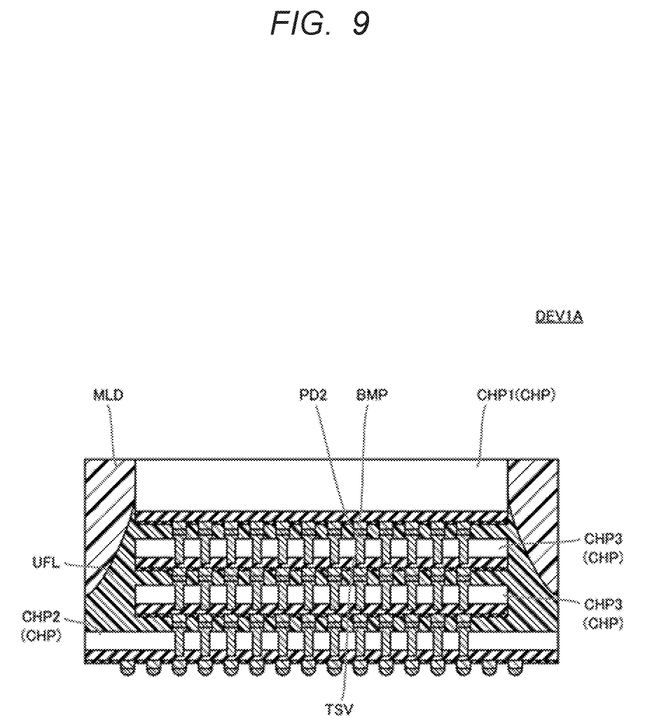

As shown in FIG. 9, in the semiconductor device DEV1A according to a comparative example, the part of the mold resin MLD located on the upper surface of semiconductor chip CHP1 is completely removed by polishing. From another perspective, the peripheral region PER is not covered by the mold resin MLD. When the part of the mold resin MLD located on the upper surface of semiconductor chip CHP1 is completely removed to ensure the heat dissipation of the semiconductor device DEV1A, stress concentrates on the peripheral region PER, causing cracks in the peripheral region PER. The occurrence of cracks due to such stress concentration becomes more pronounced as the thickness of semiconductor chip CHP1 increases.

The thickness of the semiconductor device DEV1 is standardized in advance. If the thickness of the semiconductor device DEV1 does not reach the predetermined standardized thickness, the thickness of semiconductor chip CHP1 is increased to adjust the thickness of the semiconductor device DEV1 to meet the standard. Therefore, it is difficult to avoid the above-mentioned stress concentration by reducing the thickness of semiconductor chip CHP1.

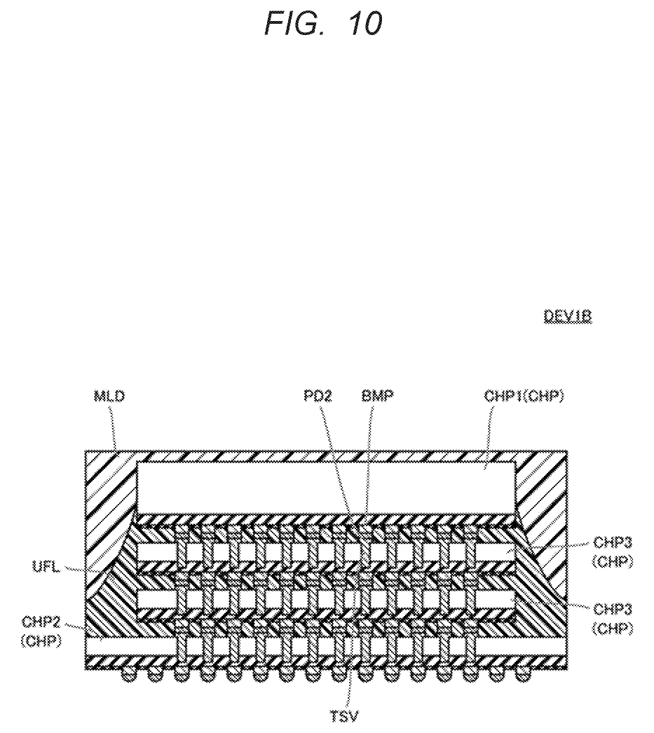

As shown in FIG. 10, in the semiconductor device DEV1B according to another comparative example, the upper surface of semiconductor chip CHP1, including the peripheral region PER, is completely covered by the mold resin MLD. Therefore, in the semiconductor device DEV1B, stress concentration on the peripheral region PER is alleviated. However, in semiconductor device DEV1B, the upper surface of semiconductor chip CHP1 is completely covered by the mold resin MLD, and because the thermal conductivity of the mold resin MLD is low, the heat dissipation is insufficient.

On the other hand, in the semiconductor device DEV1, since the mold resin MLD covers the peripheral region PER, the above-mentioned stress concentration is alleviated. Also, in the semiconductor device DEV1, since a through hole TH2 is formed in the mold resin MLD, the heat generated by semiconductor device DEV1 is easily dissipated through the through hole TH2, thus improving heat dissipation. In this way, according to the semiconductor device DEV1, it is possible to suppress stress concentration on the uppermost semiconductor chip CHP (semiconductor chip CHP1) and consequently prevent cracking while ensuring heat dissipation.

To further improve heat dissipation, a heat sink may be attached to the upper surface of the mold resin MLD. In this case, the heat dissipation pastes for attaching the heat sink is filled into the through hole TH2, promoting heat transfer between semiconductor chip CHP1 and the heat sink, so it is not necessary to completely remove the mold resin MLD on the upper surface of semiconductor chip CHP1.

### Modified Example

In the above, an example was explained where a protrusion is provided on the inner surface of the mold and the protrusion is brought into contact with the upper surface of semiconductor chip CHP1 to form the through hole TH2, but the through hole TH2 may be formed by other methods. For example, the through hole TH2 may be formed by irradiating laser light on the upper surface of the mold resin MLD after polishing the upper surface of the mold resin MLD.

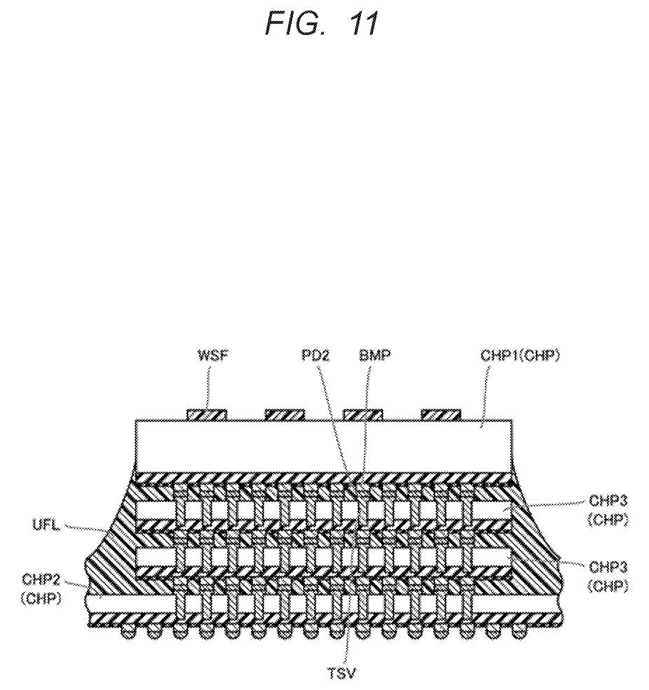

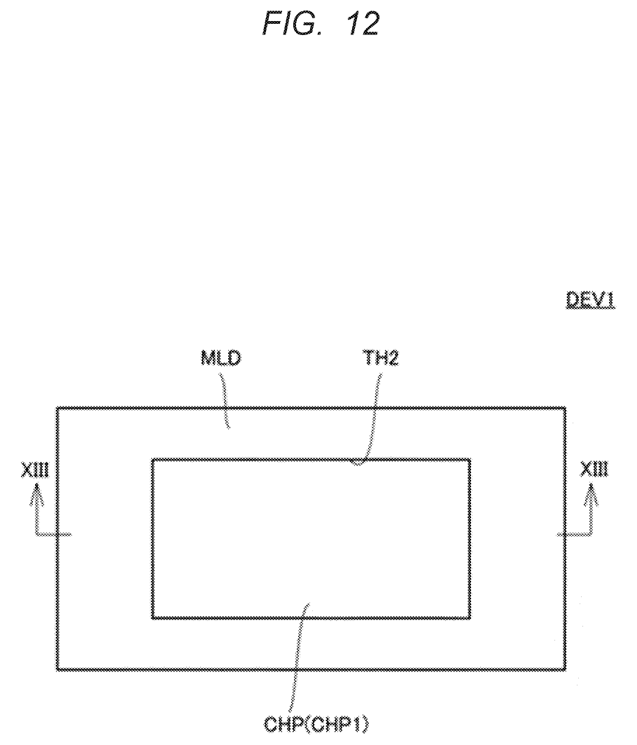

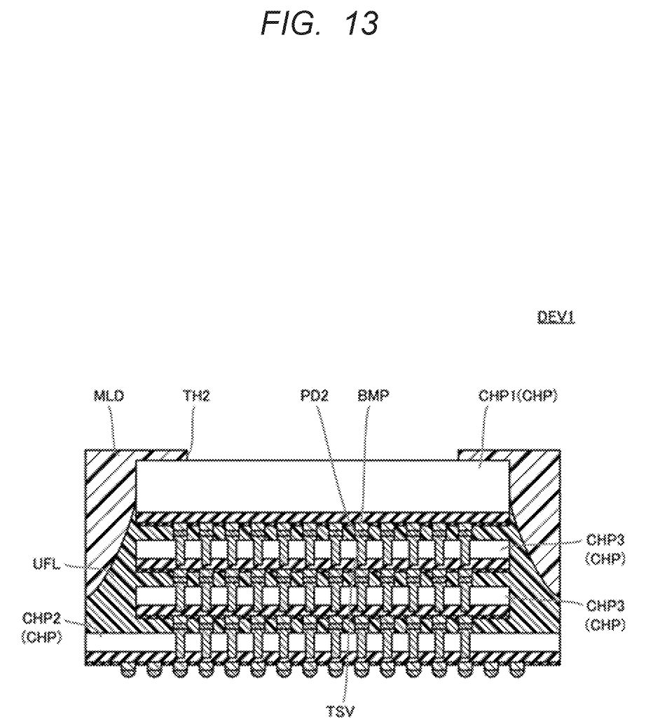

Also, as shown in FIG. 11, before sealing the plurality of semiconductor chips CHPs and underfill UFL with mold resin MLD, a water-soluble film WSF may be placed on semiconductor chip CHP1. Then, by contacting the inner surface of the mold with the water-soluble film WSF and performing sealing with mold resin MLD, the through hole TH2 is formed. The water-soluble film WSF is removed by washing with water after the formation of the through-hole TH2. In this case, it is not necessary to introduce equipment for processing protrusions on the mold or laser processing, thus reducing the manufacturing cost of semiconductor device DEV1. As shown in FIGS. 12 and 13, in semiconductor device DEV1, only one through hole TH2 is formed. Thus, it is not necessary to have a plurality of through-holes TH2s.

### Second Embodiment

The semiconductor device DEV2 according to the second embodiment will be explained. Here, the differences from semiconductor device DEV1 will be mainly explained, and repetitive explanations will not be repeated.

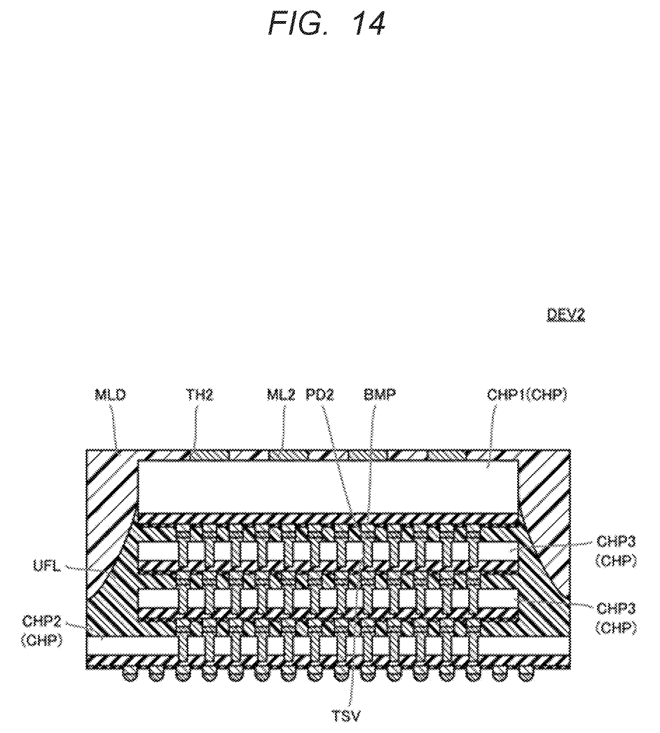

As shown in FIG. 14, semiconductor device DEV2 further includes a metal layer ML2. The metal layer ML2 is formed on the upper surface of semiconductor chip CHP1 within the through hole TH2. The metal layer ML2 is formed by the same method as the pad PD2. The metal layer ML2 is made of a material with high thermal conductivity. For example, the metal layer ML2 is made of copper or a copper alloy. In the semiconductor device DEV2, by contacting the inner surface of the mold with the metal layer ML2 and performing sealing with mold resin MLD, the through hole TH2 is formed.

In the semiconductor device DEV2, since the metal layer ML2 is arranged within the through-hole TH2, the heat generated in the semiconductor device DEV2 is more easily dissipated through the through-hole TH2. Therefore, according to semiconductor device DEV2, the heat dissipation is further improved. Additionally, in the semiconductor device DEV2, the introduction of equipment for processing such as providing protrusions in molds or laser processing to form the through-hole TH2 is unnecessary, thereby reducing the manufacturing cost of semiconductor device DEV2.

### Third Embodiment

The semiconductor device DEV3 according to the third embodiment will be described. Here, the differences from the semiconductor device DEV2 will be mainly explained, and repetitive descriptions will not be repeated.

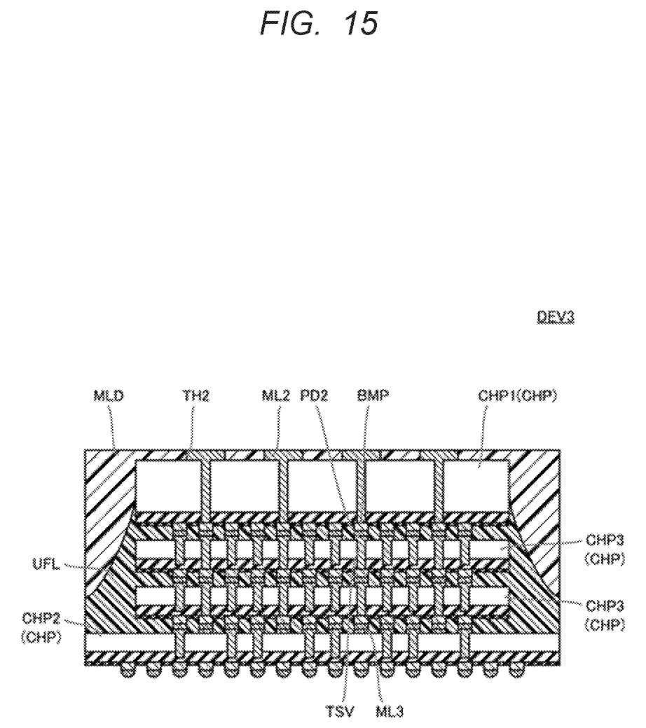

As shown in FIG. 15, in the semiconductor device DEV3, a through-hole-via TSV is also formed in the semiconductor chip CHP1. Furthermore, in the semiconductor device DEV3, a metal layer ML3 is formed on the upper surface of the semiconductor chip CHP2. The metal layer ML3 is formed of a metal material with high thermal conductivity, such as copper or copper alloy. In plain view, the metal layer ML2 and the metal layer ML3 overlap each other. The metal layer ML2 and the metal layer ML3 are connected via the through-hole-via TSV of semiconductor chip CHP1 and the through-hole-via TSV of semiconductor chip CHP3.

In semiconductor device DEV3, the heat generated in semiconductor chip CHP2 and semiconductor chip CHP3 is transmitted to the metal layer ML2 via the through-hole-via TSV and dissipated from the through-hole TH2. Therefore, in the semiconductor device DEV3, the heat dissipation is further improved.

### Fourth Embodiment

The semiconductor device DEV4 according to the fourth embodiment will be described. Here, the differences from semiconductor device DEV1 will be mainly explained, and repetitive descriptions will not be repeated.

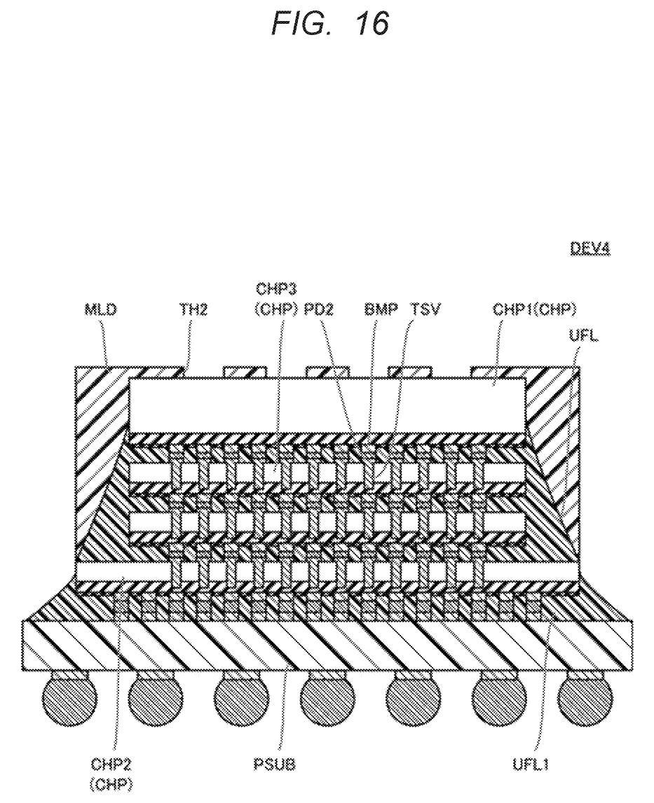

As shown in FIG. 16, the semiconductor device DEV4 further includes a wiring substrate PSUB. In the semiconductor device DEV4, a plurality of semiconductor chips CHPs are mounted on the wiring substrate PSUB. In semiconductor device DEV4, underfill UFL is filled between two of the plurality of semiconductor chips CHPs. Additionally, in semiconductor device DEV4, underfill UFL1 is filled between semiconductor chip CHP2 and the wiring substrate PSUB and is arranged on the wiring substrate PSUB to cover the side surface of semiconductor chip CHP2. In semiconductor device DEV4, mold resin MLD covers the underfill UFL and the plurality of semiconductor chips CHPs.

When mounting the plurality of semiconductor chips CHPs on the wiring substrate PSUB, semiconductor device DEV4 tends to warp due to the difference in thermal expansion rates between the wiring substrate PSUB and the semiconductor chips CHPs. However, in semiconductor device DEV4, the mold resin MLD is arranged on the wiring substrate PSUB to cover the underfill UFL and the semiconductor chips CHPs. Moreover, the difference in thermal expansion rates between the mold resin MLD and the wiring substrate PSUB is smaller than the difference between the wiring substrate PSUB and the semiconductor chips CHPs. Therefore, according to the semiconductor device DEV4, warping due to the difference in thermal expansion rates between the wiring substrate PSUB and the semiconductor chips CHPs can be suppressed.

### Fifth Embodiment

The semiconductor device DEV5 according to the fifth embodiment will be described. Here, the differences from semiconductor device DEV1 will be mainly explained, and repetitive descriptions will not be repeated.

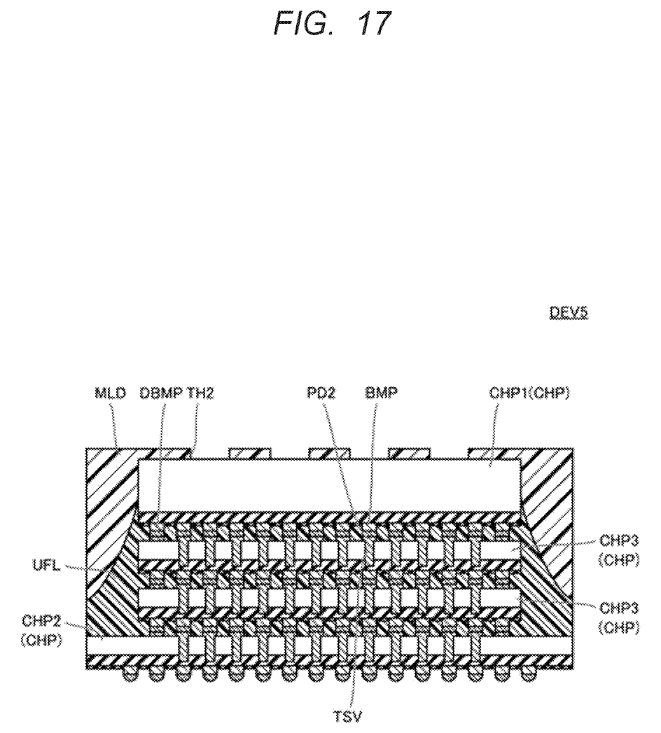

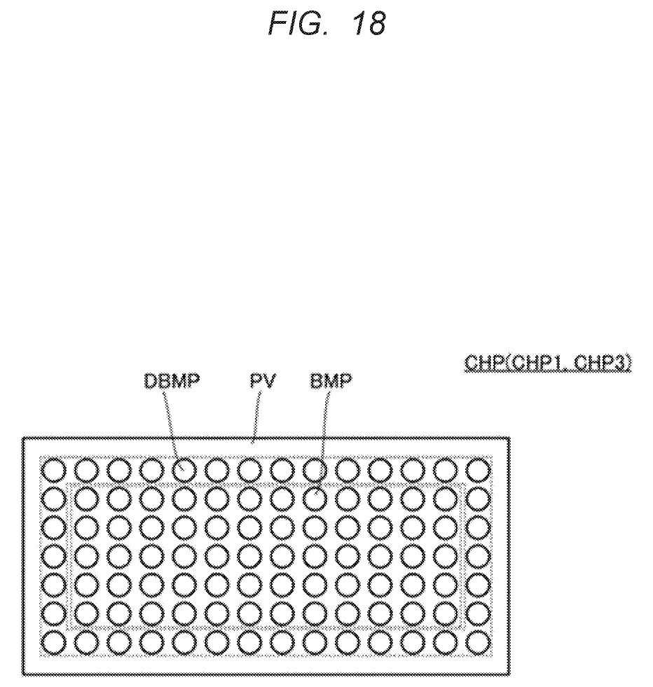

As shown in FIGS. 17 and 18, in the semiconductor device DEV5, semiconductor chips CHPs (semiconductor chip CHP1, semiconductor chip CHP3) excluding semiconductor chip CHP2 have a plurality of dummy bumps DBMPs. The structure of dummy bump DBMP is similar to the structure of bump BMP. However, while bumps BMP are electrically connected to the circuit of the semiconductor chip CHP, dummy bumps DBMP are not electrically connected to the circuit of the semiconductor chip CHP.

The bumps BMPs are arranged in a grid pattern in plain view, for example. The dummy bumps DBMPs are arranged outside the bumps BMPs in plain view. The dummy bumps DBMPs are arranged along the outer peripheral edge of the lower surface of the semiconductor chip CHP, for example. In semiconductor device DEV4, the upper semiconductor chip CHP is connected to the lower semiconductor chip CHP by both the bumps BMPs and the dummy bumps DBMPs.

In the semiconductor device DEV5, since the upper semiconductor chip CHP is connected to the lower semiconductor chip CHP by both the bumps BMPs and the dummy bumps DBMPs, the deformation of semiconductor chip CHP1 is restricted by the semiconductor chip CHP positioned lower than semiconductor chip CHP1. Therefore, according to semiconductor device DEV5, stress concentration in the outer peripheral region PER is further reduced, and consequently, the cracking of semiconductor chip CHP1 can be further suppressed. Additionally, in the semiconductor device DEV5, the heat generated in the semiconductor chip CHP positioned lower than semiconductor chip CHP1 is transmitted to semiconductor chip CHP1 via the dummy bumps DBMPs, making it easier for the heat generated in the semiconductor chip CHP positioned lower than semiconductor chip CHP1 to be dissipated through the through-hole TH2, thereby further improving heat dissipation.

### Sixth Embodiment

The semiconductor device DEV6 according to the sixth embodiment will be described. Here, the differences from semiconductor device DEV1 will be mainly explained, and repetitive descriptions will not be repeated.

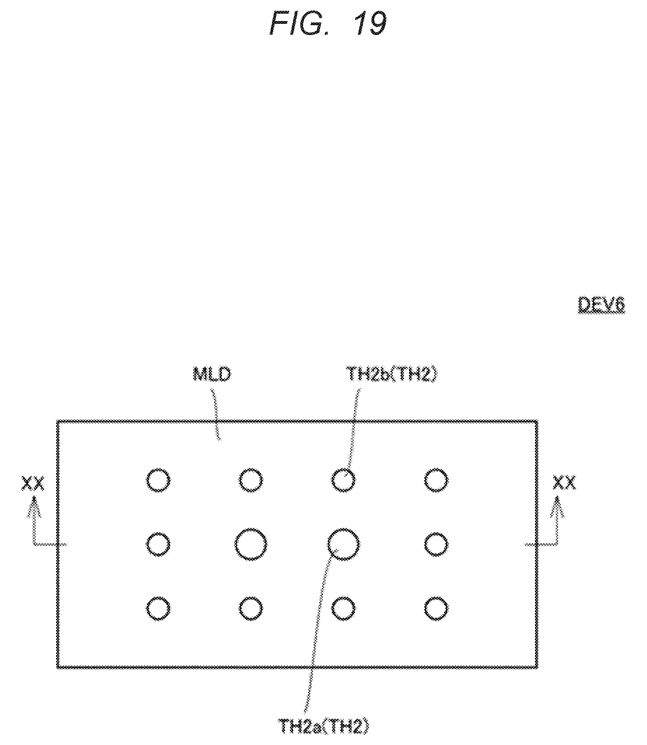

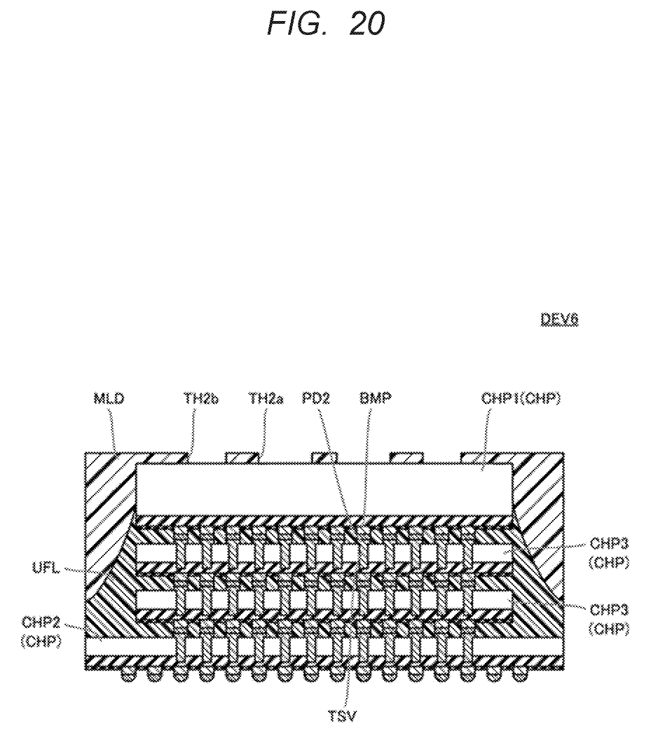

As shown in FIGS. 19 and 20, in semiconductor device DEV6, a plurality of through-holes TH2 include through-hole TH2a and through-hole TH2b. The opening area of through-hole TH2a is different from the opening area of through-hole TH2b. For example, the opening area of through-hole TH2a is larger than the opening area of through-hole TH2b.

One of the semiconductor chips CHPs generates more heat at a position overlapping with the through-hole TH2a in plain view than at a position overlapping with the through-hole TH2b in plain view. For example, the semiconductor chip CHP2 has an interface circuit with a CPU (Central Processing Unit) or DDR (Double Data Rate) memory at a position overlapping with the through-hole TH2a in plain view and has circuits with a smaller heat generation at a position overlapping with the through-hole TH2b in plain view.

When the total opening area of the through-hole TH2 is large, heat is more easily dissipated from the through-hole TH2 compared to when the total opening area of the through-hole TH2 is small. On the other hand, when the total opening area of the through-hole TH2 is large, cracks are more likely to occur in the semiconductor chip CHP1 compared to when the total opening area of the through-hole TH2 is small. In the semiconductor device DEV6, by increasing the opening area of the through-hole TH2 at a position overlapping with a circuit that generates a lot of heat in plain view, and reducing the opening area of the through-hole at a position overlapping with a circuit that does not generate much heat in plain view, it is possible to further improve heat dissipation without excessively increasing the total opening area of the through-hole TH2, thereby suppressing the occurrence of cracks in the semiconductor chip CHP1.

Although the invention made by the inventor has been specifically described based on the embodiment, the present invention is not limited to the above embodiment, and it is needless to say that various modifications can be made without departing from the gist thereof.

What is claimed is:

1. A semiconductor device comprising:
a plurality of semiconductor chips which are stacked, and
a mold resin,
wherein the plurality of semiconductor chips include at least a first semiconductor chip and a second semiconductor chip, the first semiconductor chip is located at the topmost position among the plurality of the semiconductor chips, the second semiconductor chip is located at the bottommost position among the plurality of semiconductor chips, each of the semiconductor chips has a lower surface and an upper surface located opposite the lower surface, the upper surface of the first semiconductor chip has, in a plan view, a peripheral region and a central region located inside the peripheral region, and
wherein the mold resin is formed to cover at least the peripheral region and has a through-hole that at least partially exposes the central region.

2. The semiconductor device according to claim 1, further comprising:
a first metal layer formed on the upper surface of the first semiconductor chip within the through-hole.

3. The semiconductor device according to claim 2, further comprising;
a second metal layer formed on the upper surface of the second semiconductor chip, wherein each of the plurality of semiconductor chips located above the second semiconductor chip has a through-hole-via formed to connect the first metal layer and the second metal layer.

4. The semiconductor device according to claim 1, wherein when the thickness of the first semiconductor chip is T, the width of the peripheral region is 1.6×T+0.35 mm or more.

5. The semiconductor device, according to claim 1, further comprising;
a wiring substrate,
wherein the plurality of semiconductor chips are disposed of on the wiring substrate, and the mold resin is disposed on the wiring substrate to cover the plurality of semiconductor chips.

6. The semiconductor device according to claim 1,
wherein each of the plurality of semiconductor chips located above the second semiconductor chip has a lower surface and a plurality of bumps and a plurality of dummy bumps which are formed on the lower surface, and two adjacent semiconductor chips of the plurality of semiconductor chips are coupled by the plurality of bumps and the plurality of dummy bumps, and
wherein the plurality of dummy bumps are located outside the plurality of bumps in a plan view.

7. The semiconductor device according to claim 1,
wherein the mold resin has a first through-hole and a second through-hole as the through-hole, and the opening area of the first through-hole is different from the opening area of the second through-hole.

8. The semiconductor device according to claim 7,
wherein the opening area of the first through-hole is larger than the opening area of the second through-hole, and one of the plurality of semiconductor chips generates more heat at a position overlapping with the first through-hole in a plan view than at a position overlapping with the second through-hole in a plan view.

9. The semiconductor device, according to claim 1, further comprising:
an underfill filled between two adjacent semiconductor chips of the plurality of semiconductor chips,
wherein the mold resin is formed to cover the plurality of semiconductor chips and the underfill, and
wherein the thermal expansion coefficient of the mold resin is smaller than the thermal expansion coefficient of the underfill.

10. The semiconductor device according to claim 1,
wherein the mold resin contains filler.

11. The semiconductor device according to claim 1,
wherein the thickness of the first semiconductor chip is greater than the thickness of each of the plurality of semiconductor chips located below the first semiconductor chip.

12. A method for manufacturing a semiconductor device, comprising:
stacking a plurality of semiconductor chips; and
sealing the plurality of semiconductor chips with a mold resin,
wherein the plurality of semiconductor chips include a first semiconductor chip located at the topmost position among the plurality of semiconductor chips, the upper surface of the first semiconductor chip has, in a plan view, a peripheral region and a central region located inside the peripheral region, and
wherein the mold resin is formed to cover at least the peripheral region and has a through-hole that at least partially exposes the central region.

13. The method for manufacturing a semiconductor device according to claim 12,
wherein the through-hole is formed by contacting a plurality of protrusions formed on the inner surface of a mold with the upper surface when sealing the plurality of semiconductor chips with the mold resin.

14. The method for manufacturing a semiconductor device according to claim 13,
wherein the through-hole is formed by attaching a water-soluble film to the upper surface before the sealing and then washing with water to remove the water-soluble film after the sealing with the mold resin.
